(19) United States
(12) Patent Application Publication
(10) Pub. No.: US 2017/0077090 A1
(43) Pub. Date: Mar. 16, 2017

(54) MULTI-CELL TRANSISTOR DEVICE AND METHOD OF MAKING SAME WITH CUT POLYOXIDE PROCESS FOR SELF-ALIGNED CONTACTS

(71) Applicant: QUALCOMM Incorporated, San Diego, CA (US)

(72) Inventors: Stanley Seungchul SONG, San Diego, CA (US); Kern RIM, San Diego, CA (US); Jeffrey Junhao XU, San Diego, CA (US); John Jianhong ZHU, San Diego, CA (US); Jun CHEN, San Diego, CA (US); Da YANG, San Diego, CA (US); Choh Fei YEAP, San Diego, CA (US)

(21) Appl. No.: 14/852,954

(22) Filed: Sep. 14, 2015

(51) Int. Cl. H01L 27/088; H01L 21/768; H01L 29/06; H01L 29/66; H01L 21/8234

(52) U.S. Cl. CPC H01L 27/088; H01L 29/6656; H01L 21/823437; H01L 29/0696; H01L 21/76897; H01L 21/823475; H01L 21/823462

(57) ABSTRACT

A multi-cell transistor includes gate body elements, gate tip elements extending from the gate body elements, and gate extensions extending from the gate tip elements. A patterned metal layer is provided between adjacent gate elements and at least portions of adjacent gate tip elements. Spacers are provided on the sides of each gate body element and each gate tip element to prevent the patterned metal layer from creating a short circuit between adjacent gate tip elements.

### FIELD OF DISCLOSURE

Various embodiments described herein relate to multi-cell transistor devices, and more particularly, to multi-cell transistor devices with self-aligned contacts.

### BACKGROUND

Source/drain (S/D) self-aligned contacts (SACs) have been implemented in multi-cell transistors. A typical process for making S/D SACs includes using a large self-aligned mask following an active shaping process, and using a polyoxide (PO) layer to confine the SACs to the S/D areas only. While this approach may be able to save the number of masks in the fabrication of SACs and increase the S/D contact areas, it may not be suitable for the fabrication of multi-cell transistors which have SAC opening areas extending out of respective tips of the PO layer to confine the SACs, thereby causing a short circuit between the SACs.

### SUMMARY

Exemplary embodiments of the disclosure are directed to multi-cell transistor devices and methods of making the same. In an embodiment, a multi-cell transistor device includes at least one transistor having a self-aligned contact (SAC) extending out of a tip of a polyoxide (PO) layer.

In an embodiment, a transistor is provided, the transistor comprising: an active region extending in a first direction; a plurality of gate body elements having respective ends extending in a second direction perpendicular to the first direction and through the active region, and respective outer spacer components and inner metal components; and a plurality of gate tip elements extending in the second direction from the ends of at least some of the gate body elements, the gate tip elements having respective outer spacer components and inner dielectric components.

In another embodiment, a multi-cell transistor device is provided, the multi-cell transistor device comprising: a first transistor cell; a second transistor cell adjacent to the first transistor cell and separated from the first transistor cell by an inter-cell buffer region; a first gate element comprising a first gate body, a first gate tip, and a first gate extension; and a second gate element comprising a second gate body, a second gate tip, and a second gate extension, wherein the first gate body and the second gate body comprise an outer spacer layer and an inner metal layer, wherein the first gate tip and the second gate tip comprise an outer spacer layer and an inner dielectric layer, and wherein the first gate extension and second gate extension comprise an outer spacer layer and an inner metal layer.

In yet another embodiment, method of forming a transistor is provided, the method comprising: forming a plurality of gate elements; forming a spacer on an outer surface of each of the gate elements; removing a portion of each of the gate elements to form a gate tip portion and a gate extension portion for each of the gate elements with the spacer extending between the gate tip portion and the gate extension portion; and forming a metal pattern between adjacent ones of the gate elements such that the spacer extending between the gate tip portion and the gate extension portion prevents the metal pattern from creating a short between adjacent gate tip portions.

### BRIEF DESCRIPTION OF THE DRAWINGS

The accompanying drawings are presented to aid in the description of embodiments of the disclosure and are provided solely for illustration of the embodiments and not limitation thereof.

FIG. 1 illustrates a top plan view of an embodiment of a structure formed by a process step of providing an active region and a patterned dummy polyoxide (PO) layer in an embodiment of a method of making a multi-cell transistor device.

FIG. 2 illustrates a top plan view of an embodiment of a structure formed by a process step of providing spacers around the PO segments of the patterned dummy PO layer in an embodiment of a method of making a multi-cell transistor device.

FIG. 3 illustrates a top plan view of an embodiment of a structure formed by a process step of providing a dielectric layer over the structure of FIG. 2 in an embodiment of a method of making a multi-cell transistor device.

FIG. 4 illustrates a top plan view of an embodiment of a structure formed by a process step of partial removal of a pre-metal dielectric (PMD) layer from the structure of FIG. 3 in an embodiment of a method of making a multi-cell transistor device

FIG. 5 illustrates a top plan view of an embodiment of the structure of FIG. 4 covered by a patterned mask in an embodiment of a method of making a multi-cell transistor device.

FIG. 6 illustrates a top plan view of an embodiment of the structure of FIG. 5 after the removal of exposed PO segments in an embodiment of a method of making a multi-cell transistor device.

FIG. 7 illustrates a top plan view of an embodiment of a structure after a dielectric is filled into the voids formed by the removal of the exposed PO segments in an embodiment of a method of making a multi-cell transistor device.

FIG. 8 illustrates a top plan view of an embodiment of a structure after patterned metal gates are formed on top of the remaining PO segments in an embodiment of a method of making a multi-cell transistor device.

FIG. 9 illustrates a top plan view of an embodiment of metal contact on diffusion (MD) patterning on the structure of FIG. 8 in an embodiment of a method of making a multi-cell transistor device.

FIG. 10 illustrates a top plan view of an MD layer deposited over the entire top area of the structure of FIG. 9 in an embodiment of a method of making a multi-cell transistor device.

FIG. 11 illustrates a top plan view of a structure after removing portions of the MD layer of FIG. 10 outside of the MD pattern in FIG. 9 in an embodiment of a method of making a multi-cell transistor device.

FIG. 12A illustrates a top plan view of an embodiment of a multi-cell transistor device after a patterned MD layer is formed on the structure as illustrated in FIG. 11.

FIG. 12B illustrates a sectional view taken along sectional line 150A-150B in FIG. 12A across a portion of the device including some of the dielectric segments.

FIG. 12C illustrates a sectional view taken along sectional line 160A-160B in FIG. 12A across a portion of the device including some of the metal gate elements.

FIG. 13 is a flowchart illustrating an embodiment of a method of making a multi-cell transistor device.

### DETAILED DESCRIPTION

Aspects of the disclosure are described in the following description and related drawings directed to specific embodiments. Alternate embodiments may be devised without departing from the scope of the disclosure. Additionally, well-known elements will not be described in detail or will be omitted so as not to obscure the relevant details of the disclosure.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of the embodiments. As used herein, the singular forms “a,” “an” and “the” are intended to include the plural forms as well, unless the context clearly indicates otherwise. It will be further understood that the terms “comprises,” “comprising,” “includes” or “including,” when used herein, specify the presence of stated features, integers, steps, operations, elements, and/or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise.

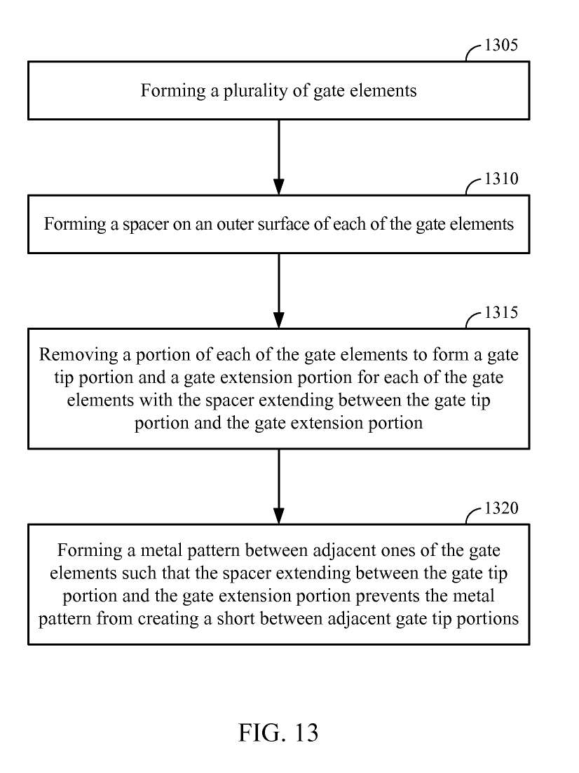

FIG. 1 illustrates a top plan view of an embodiment of a structure formed by a process step of providing an active region and a patterned dummy polyoxide (PO) layer in an embodiment of a method of making a multi-cell transistor device. Although the structural illustrations of FIGS. 1-12C and the flowchart of FIG. 13 will be described in detail below in sequence, it will be appreciated that variations, modifications, or reordering of the process steps may contemplated in the fabrication of multi-cell transistor devices within the scope of the disclosure. Referring to FIG. 1, an active region 102 is provided on a substrate 100 to form sources and drains 102a, 102b, 102c, . . . 102f of a finished multi-cell transistor device. The active region 102 may be formed on the substrate 100 in various manners known to persons skilled in the art, for example, by ion implantation with p-type or n-type dopants.

After the active region 102 is formed on the substrate 100, a patterned dummy PO layer 104 having a plurality of elongate PO segments 104a, 104b, 104c, . . . 104e is provided over the active region 102 and areas of the substrate 100 outside the active region 102. In the top plan view of the embodiment illustrated in FIG. 1, the active region 102 extends in a horizontal or first direction 106, whereas the PO segments 104a, 104b, 104c, . . . 104e of the patterned dummy PO layer 104 extend in a vertical or second direction 108 perpendicular to the first direction 106.

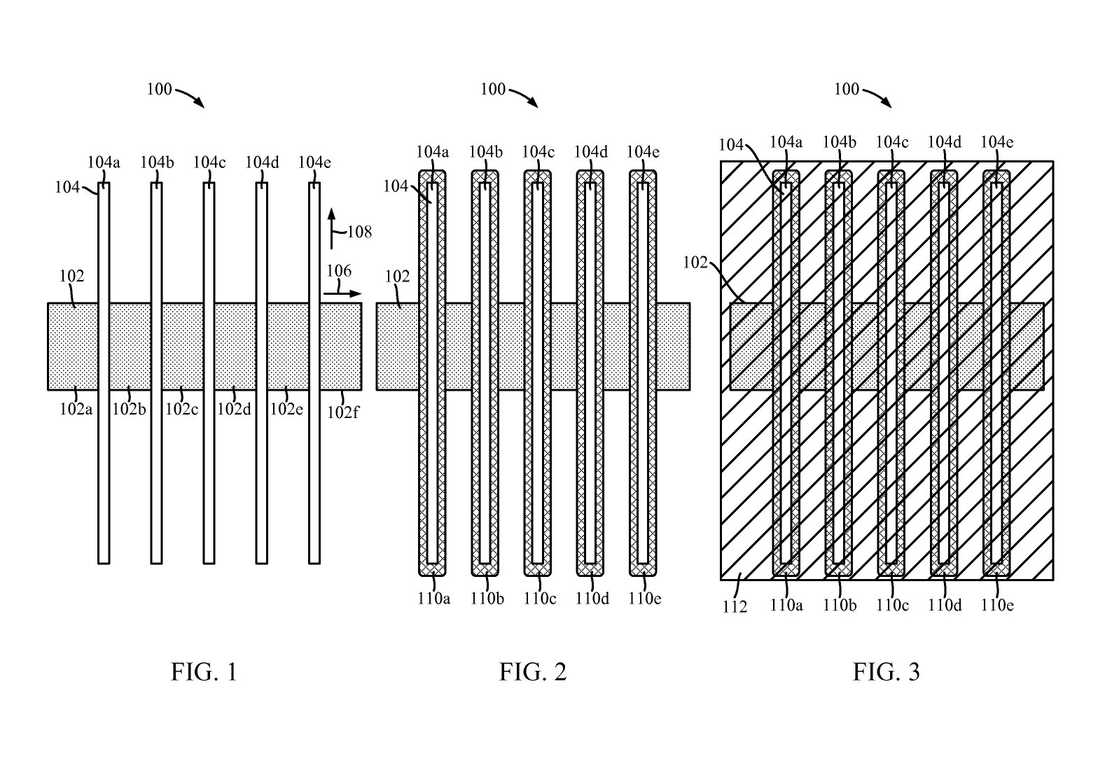

FIG. 2 illustrates a top plan view of an embodiment of a structure formed by a process step of providing spacers around the PO segments of the patterned dummy PO layer in an embodiment of a method of making a multi-cell transistor device. Referring to FIG. 2, a plurality of spacers 110a, 110b, 110c, . . . 110e are provided around the PO segments 104a, 104b, 104c, . . . 104e of the patterned dummy PO layer 104, respectively. In an embodiment, each of the spacers 110a, 110b, 110c, . . . 110e is formed immediate to the sidewalls of each of the PO segments 104a, 104b, 104c, . . . 104e. Spacers 110a, 110b, 110c, . . . 110e may be formed around the PO segments 104a, 104b, 104c, . . . 104e in various manners known to persons skilled in the art.

FIG. 3 illustrates a top plan view of an embodiment of a structure formed by a process step of providing a dielectric layer over the structure of FIG. 2 in an embodiment of a method of making a multi-cell transistor device. Referring to FIG. 3, a dielectric layer 112 is formed over all the elements exposed in the top plan view of FIG. 2, including the PO segments 104a, 104b, 104c, . . . 104e of the patterned dummy PO layer 104, the spacers 110a, 110b, 110c, . . . 110e surrounding the PO segments 104a, 104b, 104c, . . . 104e, respectively, the active region 102, and areas of the substrate 100 outside the active region 102 and not covered by the PO segments 104a, 104b, 104c, . . . 104e and the spacers 110a, 110b, 110c, . . . 110e. In an embodiment, the dielectric layer 112 may be a pre-metal dielectric (PMD) layer formed by a PMD deposition process, for example. In alternate embodiments, the dielectric layer 112 may also be provided in other manners known to persons skilled in the art.

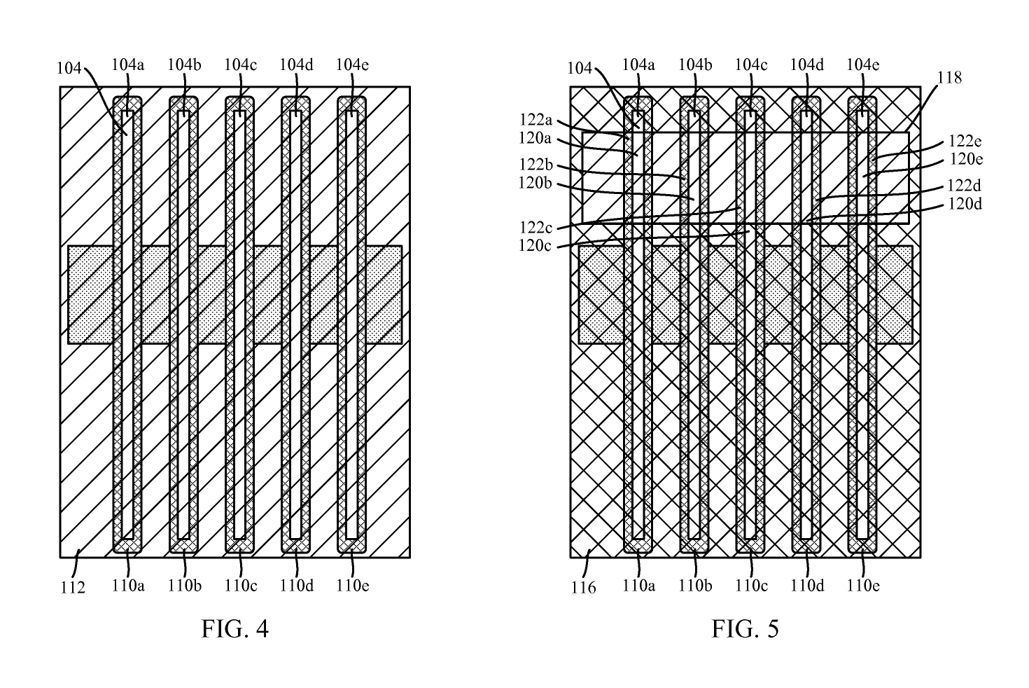

FIG. 4 illustrates a top plan view of an embodiment of a structure formed by a process step of partial removal of the PMD layer from the structure of FIG. 3 in an embodiment of a method of making a multi-cell transistor device. Referring to the top plan view of FIG. 4, the top of the dielectric layer 112 is polished or planarized in an embodiment to reveal the PO segments 104a, 104b, 104c, . . . 104e of the patterned dummy PO layer 104. In an embodiment, a chemical mechanical planarization (CMP) process is applied to reduce the height of the dielectric layer 112 to reveal the PO segments 104a, 104b, 104c, . . . 104e of the patterned dummy PO layer 104 as well as the spacers 110a, 110b, 110c, . . . 110e surrounding the PO segments 104a, 104b, 104c, . . . 104e.

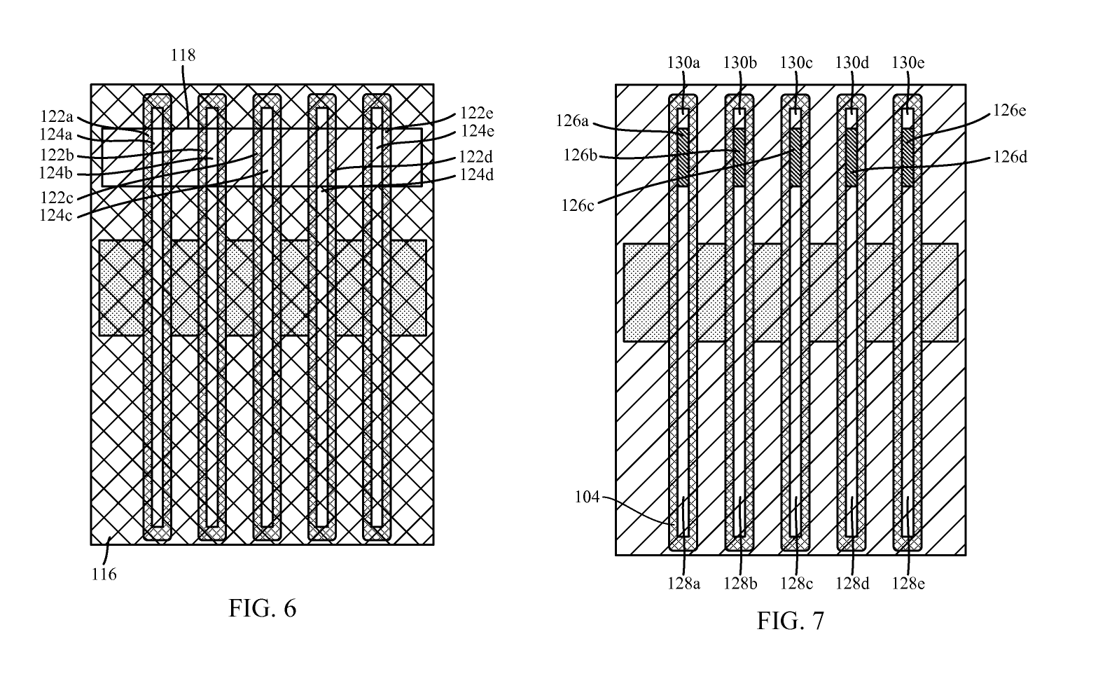

FIG. 5 illustrates a top plan view of an embodiment of the structure of FIG. 4 covered by a patterned mask in an embodiment of a method of making a multi-cell transistor device. Referring to FIG. 5, a mask 116 having an opening 118 is applied over the structure of FIG. 4. In an embodiment, the opening 118, which has a rectangular shape, only exposes segments 120a, 120b, 120c, . . . 120e of the PO segments 104a, 104b, 104c, . . . 104e of the patterned dummy PO layer 104, as well as segments 122a, 122b, 122c, . . . 122e of the spacers 110a, 110b, 110c, . . . 110e immediate to the sidewalls of the exposed PO segments 120a, 120b, 120c, . . . 120e, respectively. In an embodiment, the mask 116 may be a patterned cut PO mask with an opening 118 for subsequent removal of the exposed PO segments 120a, 120b, 120c, . . . 120e of the patterned dummy PO layer 104, as illustrated in FIG. 6.

FIG. 6 illustrates a top plan view of an embodiment of the structure of FIG. 5 after the removal of the exposed PO segments 120a, 120b, 120c, . . . 120e in an embodiment of a method of making a multi-cell transistor device. The exposed PO segments 120a, 120b, 120c, . . . 120e revealed through the opening 118 of the patterned cut PO mask 116 may be removed by etching, for example. Referring to FIG. 6, after the exposed PO segments are removed, voids 124a, 124b, 124c, . . . 124e are formed between respective sidewalls of exposed segments 122a, 122b, 122c, . . . 122e of the spacers 110a, 110b, 110c, . . . 110e.

FIG. 7 illustrates a top plan view of an embodiment of a structure after a dielectric is filled into the voids formed by the removal of exposed PO segments in an embodiment of a method of making a multi-cell transistor device. Referring to FIG. 7, the patterned cut PO mask 116 in FIGS. 5 and 6 have been removed, and a dielectric material is filled into the voids to form dielectric segments 126a, 126b, 126c, . . . 126e. As illustrated in the top plan view of FIG. 7, the dielectric segments 126a, 126b, 126c, . . . 126e separate the PO segments of the patterned dummy PO layer 104 into PO segments 128a and 130a, 128b and 130b, 128c and 130c, 128d and 130d, and 120e and 130e, respectively. In an embodiment, the dielectric material for the dielectric segments 126a, 126b, 126c, . . . 126e may be an isolation dielectric that has the same etch selectivity as PMD. In alternate embodiments, other dielectric materials may also be used within the scope of the disclosure.

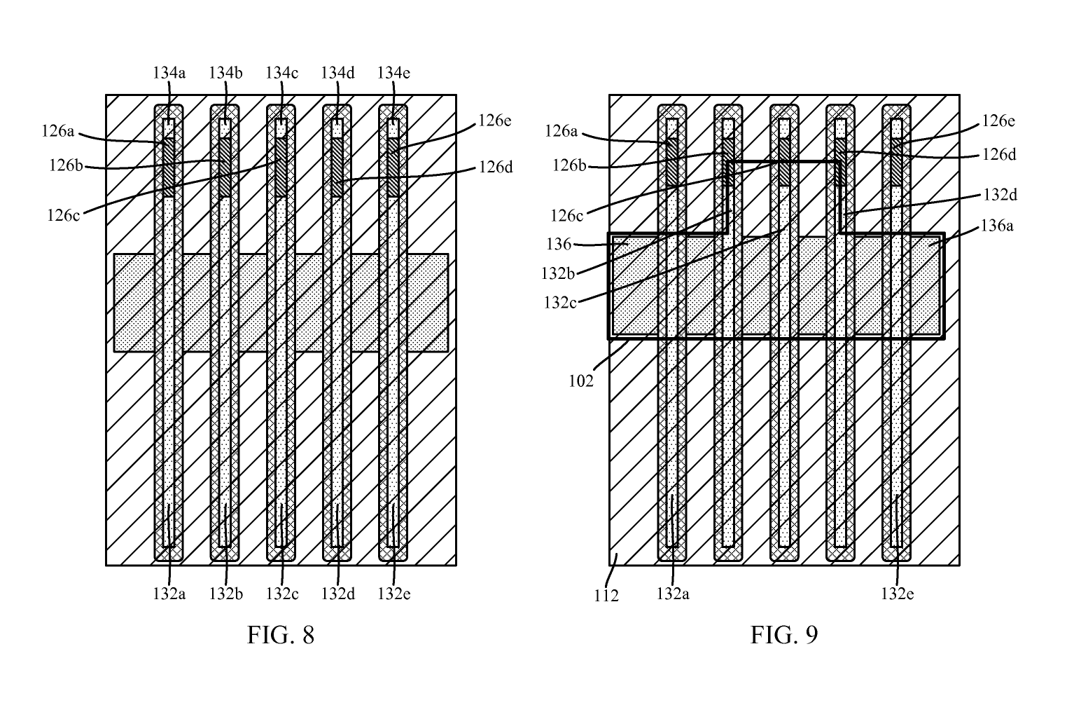

FIG. 8 illustrates a top plan view of an embodiment of a structure after patterned metal gates are formed on top of the remaining PO segments 128a, 128b, 128c, . . . 128e and 130a, 130b, 130c, . . . 130e in an embodiment of a method of making a multi-cell transistor device. Referring to FIG. 8, a first plurality of metal gate elements 132a, 132b, 132c, . . . 132e and a second plurality of metal gate elements 134a, 134b, 134c, . . . 134e are provided. In an embodiment, the first plurality of metal gate elements 132a, 132b, 132c, . . . 132e as shown in FIG. 8 are formed on top of the PO segments 128a, 128b, 128c, . . . 128e as shown in FIG. 7, respectively, and the second plurality of metal gate elements 134a, 134b, 134c, . . . 134e as shown in FIG. 8 are formed on top of the PO segments 130a, 130b, 130c, . . . 130e as shown in FIG. 7, respectively.

In an embodiment, the dielectric segments 126a, 126b, 126c, . . . 126e that separate respective PO segments 128a and 130a, 128b and 130b, 128c and 130c, 128d and 130d, and 120e and 130e as shown in FIG. 7 are not covered by metal gate elements. Instead, they provide electrical insulation between the respective metal gate elements 132a and 134a, 132b and 134b, 132c and 134c, 132d and 134d, and 132e and 134e, as shown in FIG. 8. In an embodiment, the metal gate elements 132a, 132b, 132c, . . . 132e and 134a, 134b, 134c, . . . 134e may be formed by a replacement metal gate (RMG) process followed by a metal gate (MG) hard mask (HM) process, for example. In alternate embodiments, other processes may also be used to form the metal gate elements 132a, 132b, 132c, . . . 132e and 134a, 134b, 134c, . . . 134e within the scope of the disclosure.

FIG. 9 illustrates a top plan view of an embodiment of metal contact on diffusion (MD) patterning on the structure of FIG. 8 in an embodiment of a method of making a multi-cell transistor device. Referring to the top plan view of FIG. 9, an MD pattern 136 is shaped such that it covers an area 136a of the dielectric layer 112 over the active region 102, and an extended area 136b over at least some of the metal gate elements and some of the dielectric segments outside of the active region 102. For example, in the embodiment shown in FIG. 9, the extended area 136b of the MD pattern includes areas over portions of the metal gate elements 132b, 132c and 132d outside of the active region 102, portions of the dielectric segments 126b, 126c and 126d which extend from the metal gate elements 132b, 132c and 132d, respectively, and areas of the dielectric layer 112 between these portions of metal gate elements and dielectric segments.

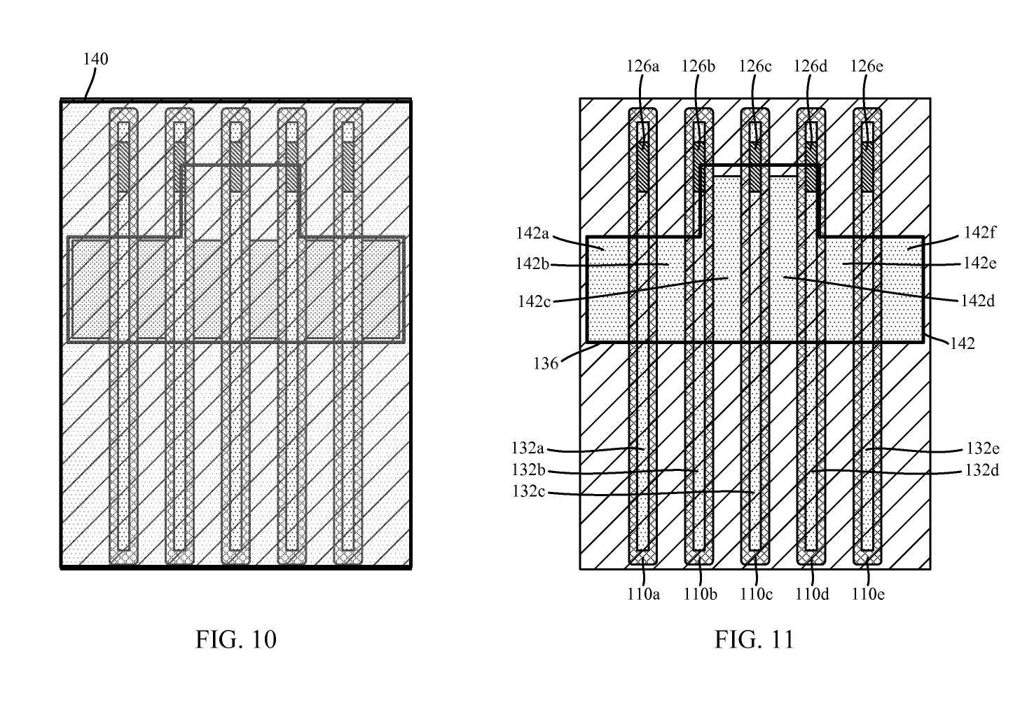

FIG. 10 illustrates a top plan view of an MD layer 140 deposited over the entire top area of the structure of FIG. 9 in an embodiment of a method of making a multi-cell transistor device. FIG. 11 illustrates a top plan view of a structure after removing portions of the MD layer 140 of FIG. 10 outside of the MD pattern 136 in FIG. 9 in an embodiment of a method of making a multi-cell transistor device. Referring to FIG. 11, a patterned MD layer 142 includes areas 142a, 142b, 142c, . . . 142f after selective removal of the portions of the MD layer outside of the MD pattern 136. Moreover, in an embodiment, a CMP process may be applied to the MD layer to remove the MD material on top of portions of the metal gate elements 132a, 132b, 132c, . . . 132e and respective portions of the spacers 110a, 110b, 110c, . . . 110e within the MD pattern 136. Other processes known to persons skilled in the art may also be used to selectively remove the MD layer.

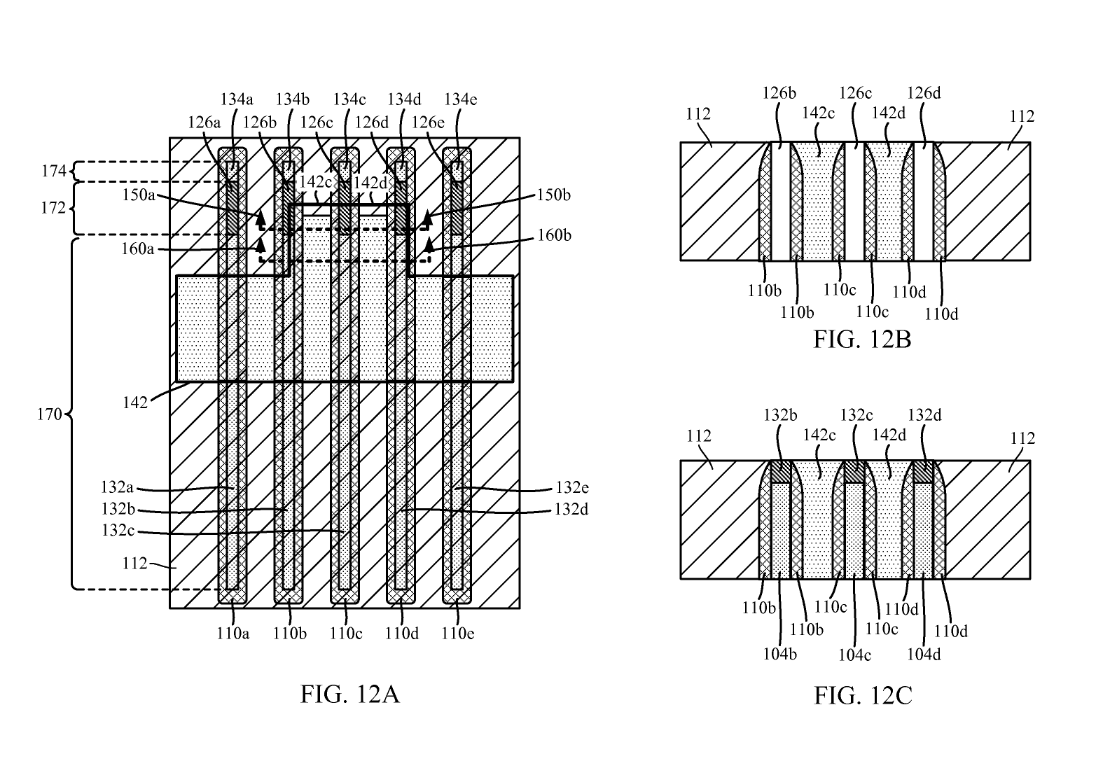

FIG. 12A illustrates a top plan view of an embodiment of a multi-cell transistor device after the patterned MD layer is formed on the structure as illustrated in FIG. 11. FIG. 12B illustrates a sectional view taken along sectional line 150A-150B in FIG. 12A across a portion of the device including dielectric segments 126b, 126c and 126d. FIG. 12C illustrates a sectional view taken along sectional line 160A-160B in FIG. 12A across a portion of the device including metal gate elements 132b, 132c and 132d. In the top plan view of FIG. 12A, each of the gate elements 132a, 132b, 132c, . . . 132e may be regarded as having three distinct segments, including a gate body element 170, a gate tip element 172 and a gate extension element 174. The gate body element 170 of each gate element has a top metal gate. The gate tip element 172 extends from an end of the gate body element and has an isolation dielectric. The gate extension element 174 further extends from the gate tip element and has a top metal gate.

The gate tip element 172, which includes the isolation dielectric, thus separates the metal gates of the gate body element 170 and the gate extension element 174. Moreover, in the top plan view of FIG. 12A, each of the spacers 110a, 110b, 110c, . . . 110e surrounds all three portions, namely, the gate body element 170, the gate tip element 172 and the gate extension element 174, of each of the gate elements 132a, 132b, 132c, . . . 132e, respectively.

FIG. 12B, which is the section view taken along sectional line 150A-150B in FIG. 12A, shows the dielectric segments 126b, 126c and 126d with sidewalls surrounded by the spacers 110b, 110c and 110d, respectively. This sectional view also illustrates a portion 142c of the MD layer 142 that separates the spacers 110b and 110c around the dielectric segments 126b and 126c, respectively, and another portion 142d of the MD layer 142 that separates the spacers 110c and 110d around the dielectric segments 126c and 126d, respectively. In an embodiment, the dielectric layer 112, which may comprises a PMD layer, remains on the left and right sides of the spacers 110b and 110d around the dielectric segments 126b and 126d, respectively.

FIG. 12C, which is the section view taken along sectional line 160A-160B in FIG. 12A, shows the metal gate segments 132b, 132c and 132d, which are positioned above the PO segments 104b, 104c and 104d, respectively. The sidewalls of the metal gate segments 132b, 132c and 132d and respective PO segments 104b, 104c and 104d are surrounded by the spacers 110b, 110c and 110d, respectively. This sectional view also illustrates portions 142c and 142d of the MD layer 142 that separate the spacers of the adjacent gate elements. In an embodiment, the dielectric layer 112, which may comprises a PMD layer, remains on the left and right sides of the spacers 110b and 110d, respectively.

Referring back to the top plan view of FIG. 12A, the portions 142c and 142d of the MD layer 142 do not extend beyond the gate extension elements 174 of the metal gates 134b, 134c and 134d. Moreover, these MD portions 142c and 142d are separated by the spacer 110c, and thus no electric short circuit is created between the MD portions 142c and 142d. Although the multi-cell transistor device as shown in FIG. 12A includes two extended MD portions 142c and 142d between the gate elements 132b, 132c and 132d, it will be appreciated that the MD layer 142 may include other extensions between other adjacent gate elements within the scope of the disclosure.

FIG. 13 is a flowchart illustrating an embodiment of a method of making a multi-cell transistor device. In FIG. 13, a plurality of gate elements is formed in block 1305, and a spacer on an outer surface of each of the gate elements is formed in block 1310. A portion of each of the gate elements is removed to form a gate tip portion and a gate extension portion for each of the gate elements with the spacer extending between the gate tip portion and the gate extension portion in block 1315. A metal pattern is formed between adjacent ones of the gate elements such that the spacer extending between the gate tip portion and the gate extension portion prevents the metal pattern from creating a short between adjacent gate tip portions in block 1320.

In an embodiment, the gate elements may be formed by providing a metal gate layer, using one or more metal gate processes such as an RMG process followed by an MG HM process as described above, for example. Other processes may also be used in forming the gate elements within the scope of the disclosure. In an embodiment, a metal portion of each of the gate elements is removed to form a gate tip portion and a gate extension portion. In a further embodiment, a dielectric is provided in the gate tip portion to isolate the gate extension portion from the remainder of the gate element which is the gate body portion. In an embodiment, the metal pattern between adjacent gate elements is formed by using a patterned metal deposition layer, such as an MD layer, for example. In a further embodiment, a PMD layer is formed in areas between adjacent gate elements outside of the areas covered by the metal pattern.

While the foregoing disclosure shows illustrative embodiments, it should be noted that various changes and modifications could be made herein without departing from the scope of the appended claims. The functions, steps or actions of the method claims in accordance with embodiments described herein need not be performed in any particular order unless expressly stated otherwise. Furthermore, although elements may be described or claimed in the singular, the plural is contemplated unless limitation to the singular is explicitly stated.

What is claimed is:

1. A transistor comprising:
an active region extending in a first direction;
a plurality of gate body elements having respective ends extending in a second direction perpendicular to the first direction and through the active region, and respective outer spacer components and inner metal components; and
a plurality of gate tip elements extending in the second direction from the ends of at least some of the gate body elements, the gate tip elements having respective outer spacer components and inner dielectric components.

2. The transistor of claim 1, wherein the inner metal components of the gate body elements comprise portions of a metal gate layer.

3. The transistor of claim 1, further comprising a metal contact on diffusion (MD) layer comprising a plurality of MD portions between the outer spacer components of adjacent ones of the gate body elements.

4. The transistor of claim 3, wherein the MD layer further comprises a plurality of extended MD portions between the outer spacer components of adjacent ones of some of the gate tip elements.

5. The transistor of claim 4, wherein the extended MD portions are positioned between the outer spacer components of adjacent ones of some but not all of the gate tip elements.

6. The transistor of claim 4, further comprising a pre-metal dielectric (PMD) layer comprising PMD portions between the outer spacer components of adjacent ones of the gate body elements not occupied by the MD portions.

7. The transistor of claim 6, wherein the PMD layer further comprises additional PMD portions between the outer spacer components of adjacent ones of the gate tip elements not occupied by the extended MD portions.

8. The transistor of claim 1, wherein the active region comprises a plurality of sources and drains.

9. A multi-cell transistor device comprising:
a first transistor cell;
a second transistor cell adjacent to the first transistor cell and separated from the first transistor cell by an inter-cell buffer region;
a first gate element comprising a first gate body, a first gate tip, and a first gate extension; and
a second gate element comprising a second gate body, a second gate tip, and a second gate extension,
wherein the first gate body and the second gate body comprise an outer spacer layer and an inner metal layer,
wherein the first gate tip and the second gate tip comprise an outer spacer layer and an inner dielectric layer, and
wherein the first gate extension and second gate extension comprise an outer spacer layer and an inner metal layer.

10. The multi-cell transistor device of claim 9, further comprising a metal contact on diffusion (MD) layer comprising an MD portion in the inter-cell buffer region between at least a portion of the first gate body and at least a portion of the second gate body.

11. The multi-cell transistor device of claim 10, wherein the MD layer further comprises an extended MD portion in the inter-cell buffer region between at least a portion of the first gate tip and at least a portion of the second gate tip.

12. The multi-cell transistor device of claim 11, further comprising a pre-metal dielectric (PMD) layer comprising a PMD portion in the inter-cell buffer region between at least a portion of the first gate body and at least a portion of the second gate body not occupied by the MD layer.

13. The multi-cell transistor device of claim 12, wherein the PMD layer further comprises a second PMD portion in the inter-cell buffer region between at least a portion of the first gate tip and at least a portion of the second gate tip not occupied by the extended MD portion.

14. The multi-cell transistor device of claim 13, wherein the PMD layer further comprises a third PMD portion in the inter-cell buffer region between the first gate extension and the second gate extension.

15. A method of forming a transistor, the method comprising:
forming a plurality of gate elements;
forming a spacer on an outer surface of each of the gate elements;
removing a portion of each of the gate elements to form a gate tip portion and a gate extension portion for each of the gate elements with the spacer extending between the gate tip portion and the gate extension portion; and
forming a metal pattern between adjacent ones of the gate elements such that the spacer extending between the gate tip portion and the gate extension portion prevents the metal pattern from creating a short between adjacent gate tip portions.

16. The method of claim 15, wherein removing the portion of each of the gate elements comprises removing a metal portion from each of the gate elements.

17. The method of claim 15, further comprising providing a dielectric in the gate tip portion.

18. The method of claim 15, wherein forming the metal pattern comprises forming a patterned metal contact on diffusion (MD) layer.

19. The method of claim 18, further comprising forming a pre-metal dielectric (PMD) layer in areas between adjacent ones of the gate elements not covered by the metal pattern.

20. The method of claim 15, wherein forming the gate elements comprises forming a metal gate layer.
